(19) United States
(12) Patent Application Publication
(10) Pub. No.: US 2024/0429095 A1
(43) Pub. Date: Dec. 26, 2024

(54) MULTI-AXIS LASER DRILLING FOR WAFER-LEVEL PACKAGING

(71) Applicant: STMicroelectronics International N.V., Geneva (CH)

(72) Inventor: Shei Meng LOO, Singapore (SG)

(21) Appl. No.: 18/733,373

(22) Filed: Jun. 4, 2024

Related U.S. Application Data
(60) Provisional application No. 63/509,312, filed on Jun. 21, 2023.

(51) Int. Cl. H01L 21/768; H01L 21/04; H01L 21/304; H01L 21/48

(52) U.S. Cl. CPC H01L 21/76894; H01L 21/043; H01L 21/304; H01L 21/4857

(57) ABSTRACT

A method of relocation of input/output (I/O) contact pads in a wafer-level package is provided. A method of manufacturing a wafer-level package can include: forming a redistribution layer on a wafer having a contact pad disposed thereon, where the wafer defines a plane along a major horizontal surface on which the contact pad is disposed; drilling, with a multi-axis laser drill, a hole along an axis through the redistribution layer to reach the contact pad, where the axis of the hole through the redistribution layer is at an angle relative to the plane that is neither parallel nor orthogonal; and forming a contact extending from the contact pad, through the hole through the redistribution layer, to a position on the redistribution layer.

### CROSS-REFERENCE TO RELATED APPLICATIONS

This application claims priority to U.S. Provisional Patent Application Ser. No. 63/509,312, filed on Jun. 21, 2023, the contents of which are hereby incorporated by reference in their entirety.

### TECHNOLOGICAL FIELD

Example embodiments of the present disclosure relate generally to relocation of input/output (I/O) contact pads in a wafer-level package, and more particularly, using a multi-axis laser drill to drill off-vertical holes through a redistribution layer in order to relocate I/O contact pads in a wafer-level package.

### BACKGROUND

The demand for semiconductors is ever-increasing as new technology requiring semiconductors is developed. Further, as electronic devices are developed, smaller, thinner form factors have become increasingly desirable and achievable. Semiconductor packages for electronic devices continue to shrink in size and be placed closer together. These semiconductor packages, as well as other components of electronic devices have some parameters of their sizes dictated by features other than the underlying semiconductor chip.

As demand increases, production of semiconductor chips and packages struggles to keep up. Manufacturing efficiencies are exceedingly important to increase production volume by reducing the time required to produce semiconductor chip packages. Further, manufacturing quality is critical to ensure the semiconductor chip packages that are produced meet the necessary standards for product to avoid waste and to further improve manufacturing efficiency.

New systems, apparatuses, and methods for semiconductor manufacturing are needed. The inventor have identified numerous areas of improvement in the existing technologies and processes, which are the subjects of embodiments described herein. Through applied effort, ingenuity, and innovation, many of these deficiencies, challenges, and problems have been solved by developing solutions that are included in embodiments of the present disclosure, some examples of which are described in detail herein.

### BRIEF SUMMARY

Various embodiments described herein relate to relocation of input/output (I/O) contact pads in a wafer-level package, and more particularly, using a multi-axis laser drill to drill off-vertical holes through a redistribution layer in order to relocate I/O contact pads in a wafer-level package. In accordance with some embodiments of the present disclosure, an example method is provided. Embodiments provided herein include a method of manufacturing a wafer-level package including: forming a redistribution layer on a wafer having a contact pad disposed thereon, where the wafer defines a plane along a major horizontal surface on which the contact pad is disposed; drilling, with a multi-axis laser drill, a hole along an axis through the redistribution layer to reach the contact pad, where the axis of the hole through the redistribution layer is at an angle relative to the plane that is neither parallel nor orthogonal; and forming a contact extending from the contact pad, through the hole through the redistribution layer, to a position on the redistribution layer.

According to some embodiments, the axis of the hole through the redistribution layer is at an angle relative to the plane that is between 10 degrees and 80 degrees. The methods of some embodiments further include: forming a seed layer after drilling; and applying a photoresist dry film lamination layer over the seed layer, where the contact extending from the contact pad is formed where the photoresist dry film lamination layer was not cured. Methods of some embodiments further include: applying a solder mask over the redistribution layer; and attaching a solder ball at the contact that is in electrical communication with the contact pad. The redistribution layer includes, in some embodiments, Ajinomoto Build-up Film. The contact pad of some embodiments is a contact pad of an input/output (I/O) portion of a semiconductor chip. According to some embodiments, methods may include determining the angle relative to the plane for the hole through the redistribution layer is based on a thickness of the redistribution layer and a required position of the contact relative to the contact pad. The hole of some embodiments is around 25 microns.

According to some embodiments, the contact pad is a first contact pad, the hole is a first hole, the axis is a first axis, the contact is a first contact, and the angle is a first angle, the method further including: drilling, with the multi-axis laser drill, a second hole along a second axis through the redistribution layer to reach a second contact pad of the wafer, where the second axis of the second hole through the redistribution layer is at a second angle relative to the plane that is different from the first angle; and forming a second contact extending from the second contact pad, through the hole through the redistribution layer, to a position on the redistribution layer opposite the wafer. According to some embodiments, drilling a hole along the axis through the redistribution layer to reach the contact pad further includes removing one or more of friction-melted resin or drilling debris from the hole after drilling. According to some embodiments, removing one or more of friction-melted resin or drilling debris from the hole after drilling includes treating the hole using at least one of permanganate or plasma treatment

Embodiments provided herein include a wafer-level package including: a silicon wafer, where the silicon wafer defines a plane along a major horizontal surface; a contact pad on the major horizontal surface of the silicon wafer; a redistribution layer on the silicon wafer; a hole through the redistribution layer, where the hole defines an axis along which the hole extends, where the axis is at an angle relative to the plane of between about 10 degrees and 80 degrees; and a contact extending from the contact pad, through the hole through the redistribution layer, to a position on the redistribution layer opposite the wafer.

According to some embodiments, the hole through the redistribution layer is formed using a multi-axis laser drill. The wafer-level package of some embodiments further includes: a solder mask over the redistribution layer and a solder ball on the contact that is in electrical communication with the contact pad. The contact pad of some embodiments is a contact pad of an input/output (I/O) portion of a semiconductor chip. The hole of some embodiments is around 25 microns in diameter.

Embodiments provided herein include a system for producing a wafer-level package including: a wafer having contact pads and a redistribution layer covering a major surface of the wafer and the contact pads; a multi-axis laser drill, where the multi-axis laser drill is configured to drill holes at various different angles relative to a plane defined by the major surface of the wafer through the redistribution layer to reach at least one of the contact pads. The multi-axis laser drill of some embodiments is configured to drill holes at between about 10 degrees and about 80 degrees from the plane defined through the wafer. The multi-axis laser drill of some embodiments is configured to drill holes through the redistribution layer of at least 25 microns in diameter.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF SUMMARY OF THE DRAWINGS

Having thus described certain example embodiments of the present disclosure in general terms, reference will now be made to the accompanying drawings, which are not necessarily drawn to scale, and wherein:

FIG. 1 illustrates a top view of a semiconductor package according to an example embodiment of the present disclosure;

FIG. 2A illustrates a cross-section of a wafer and contact pad according to example embodiments of the present disclosure;

FIG. 2B illustrates the cross-section of FIG. 2A with a redistribution layer according to an example embodiment of the present disclosure;

FIG. 2C illustrates an aperture formed in the redistribution layer of FIG. 2B according to an example embodiment of the present disclosure;

FIG. 2D illustrates the wafer-level package of FIG. 2C with an electroless copper seed layer according to an example embodiment of the present disclosure;

FIG. 3A illustrates the wafer-level package of FIG. 2D with a photoresist dry film lamination applied according to an example embodiment of the present disclosure;

FIG. 3B illustrates the wafer-level package of FIG. 3A with the photoresist dry film lamination imaged and developed according to an example embodiment of the present disclosure;

FIG. 3C illustrates the wafer-level package of FIG. 3B with a copper trace deposited according to an example embodiment of the present disclosure;

FIG. 3D illustrates the wafer-level package of FIG. 3C with the photoresist dry film lamination removed and the seed layer etched according to an example embodiment of the present disclosure;

FIG. 4A illustrates the wafer-level package of FIG. 3D with a second redistribution layer and second copper trace according to an example embodiment of the present disclosure;

FIG. 4B illustrates the wafer-level package of FIG. 4A with a solder mask applied according to an example embodiment of the present disclosure;

FIG. 4C illustrates the wafer-level package of FIG. 4B with a solder ball applied according to an example embodiment of the present disclosure;

FIG. 5A illustrates a cross-section of a wafer and contact pad according to example embodiments of the present disclosure;

FIG. 5B illustrates the cross-section of FIG. 5A with a redistribution layer according to an example embodiment of the present disclosure;

FIG. 5C illustrates a hole drilled by a multi-axis laser drill in the redistribution layer of FIG. 5B according to an example embodiment of the present disclosure;

FIG. 6A illustrates the wafer-level package of FIG. 5C with an electroless copper seed layer according to an example embodiment of the present disclosure;

FIG. 6B illustrates the wafer-level package of FIG. 6A with a photoresist dry film lamination applied and cured according to an example embodiment of the present disclosure;

FIG. 6C illustrates the wafer-level package of FIG. 6B with a copper trace deposited according to an example embodiment of the present disclosure;

FIG. 7A illustrates the wafer-level package of FIG. 6C with the photoresist dry film lamination removed and the seed layer etched according to an example embodiment of the present disclosure;

FIG. 7B illustrates the wafer-level package of FIG. 7A with a solder mask applied according to an example embodiment of the present disclosure;

FIG. 7C illustrates the wafer-level package of FIG. 7A with a solder ball applied according to an example embodiment of the present disclosure;

FIG. 8A illustrates a wafer-level package having a relatively thin redistribution layer according to an example embodiment of the present disclosure;

FIG. 8B illustrates a wafer-level package having a relatively thicker redistribution layer according to an example embodiment of the present disclosure; and

FIG. 9 is a flowchart of a method of manufacturing a wafer-level package using a multi-axis laser drill to relocate a contact pad on a redistribution layer according to an example embodiment of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in various embodiments,” “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments or it may be excluded.

The use of the term “circuitry” as used herein with respect to components of a system or an apparatus should be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, communications circuitry, input/output circuitry, and the like. In some embodiments, other elements may provide or supplement the functionality of particular circuitry.

Various embodiments of the present disclosure are directed to improved systems, apparatuses, and methods for manufacture of semiconductor packages, and specifically to use of a multi-axis laser drill to drill off-vertical holes through a redistribution layer in order to relocate input/output (I/O) contact pads in a wafer-level package. Wafer-level packaging of semiconductor chips is critical to the production of integrated circuits for use in a wide array of electronic devices. As technology advances, the use of integrated circuits in electronic devices increases exponentially. To meet this demand, manufacturing processes need to be improved to effectively and efficiently produce wafer-level packages for the wide variety of uses. Embodiments described herein provide a mechanism by which operations from conventional wafer-level packaging manufacture can be omitted, thereby improving throughput efficiency in manufacturing and reducing the opportunity for defects in the wafer-level package.

Electronic devices, such as mobile phones, are highly portable and frequently carried throughout a user's day. As such, the size of a mobile phone or other portable electronic device is critical to the portability and use of such a device. These electronic devices have very high levels of functionality and are required to be robustly designed to stand up to frequent use and often, unintentional abuse and wear. Thus, the structure of theses electronic devices requires some degree of rigidity while maintaining a small form factor. The substantially rigid chassis of an electronic device which carries the hardware components thereof (e.g., the sensors, communications modules, speakers, cameras, screen, etc.) becomes a substantial component of the overall size, which limits the available space for the hardware components. The competing hardware components need to be sized to fit within the small form factor, otherwise components will be omitted, which adversely impacts functionality and desirability of the electronic device. As such, a small form factor for a wafer-level package for one or more sensors is highly desirable, and smaller components enable the electronic device form factor to be made smaller and/or enables the inclusion of more components increasing the functionality of the electronic device.

Wafer-level packaging provides an efficient manufacturing process through which an integrated circuit is fabricated, and components of the wafer-level package are attached to the integrated circuit before it is singulated into an individual wafer-level package to be used in a device. The components such as top and bottom layers of the packaging and solder bumps are attached to the integrated circuit through a process that does not require handling of individual integrated circuits. This process enables efficient and consistent packaging assembly to the integrated circuit without requiring an individual integrated circuit to be handled and aligned in order to assemble the components thereon.

Wafer-level packaging enables the manufacturing of an integrated circuit in a streamlined and efficient process while producing a package that has a highly compact overall size. The integrated circuits assembled into wafer-level packages can be used in a variety of end products. Different end products may have different requirements for pin or solder ball connections including different layouts and spacing. Thus, while a variety of wafer-level package may be produced using a single integrated circuit having a fixed pattern of contacts, the wafer-level package into which the integrated circuit is formed may require adjustment of a location of the pin or solder ball connections of the wafer-level package.

Conventionally, wafer-level packaging uses numerous redistribution layers (RDL) to route connections from the integrated circuit to the I/O area of the wafer-level package. The process involves producing multiple layers of Ajinomoto Build-up Film (ABF), with each layer moving the connection of the integrated circuit some degree away from the original location. The process includes layering ABF on top of the integrated circuit, drilling the ABF to expose the integrated circuit contact, depositing a copper seed layer, employing a photoresist dry film lamination patterned to receive copper plating, and depositing the copper in the masked area of the photoresist film layer. The photoresist film layer is then removed, and the process is repeated for as many RDLs as required to achieve the movement of the integrated contacts to the I/O area of the wafer-level package. This process can become cumbersome with numerous layers and operations. Embodiments described herein improve upon the process above through use of a multi-axis laser drill as described further below.

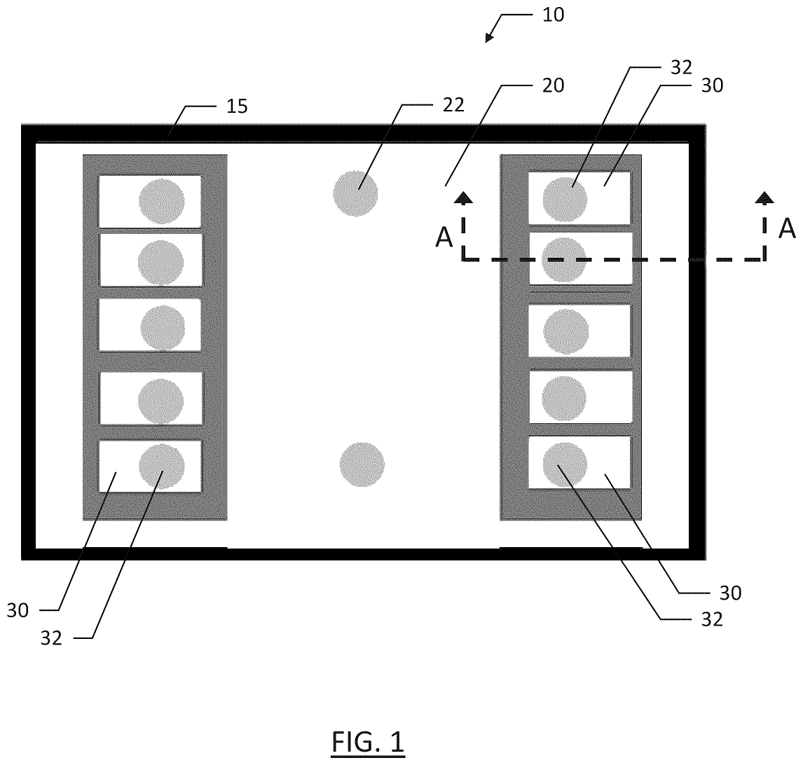

FIG. 1 illustrates a top-view of an example embodiment of a semiconductor package in accordance with one or more embodiments of the present disclosure. A semiconductor package 10 may include a dielectric layer 15, a ground plane 20, a plurality of signal pads 30, and a plurality of solder balls, such as ground plane solder balls 22 and signal pad solder balls 32. The dielectric layer may be a polyimides (PI) and/or polybenzoxazoles (PBO) material. FIG. 1 further depicts section line A-A representing a section line where cross-sectional views of subsequent figures are taken of various embodiments.

It will be readily appreciated that while only several of the signal pads 30 and signal pad solder balls 32 are referenced with numbers, the semiconductor package 10 may include a plurality of each as shown in FIG. 1. Each of the signal pads 30 may be separated from the ground plane 20 by one or more layers and/or portions of dielectric material (e.g., dielectric layer 15). When the semiconductor package 10 is used in an electronic device, the plurality of solder balls (e.g. ground plane solder balls 22 and signal pad solder balls 32) may connect the semiconductor package to other circuitries of the electronic device. While the semiconductor package 10 is illustrated as a rectangle, it will be readily appreciated that the semiconductor package 10 may take other shapes and/or dimensions, particularly as required by an electronic device. The semiconductor package 10 of FIG. 1 is an example of a view of various semiconductor configurations as described herein, such that further figures will be described with views taken along section line A-A while the cross-section views may depict different embodiments of a semiconductor package 10.

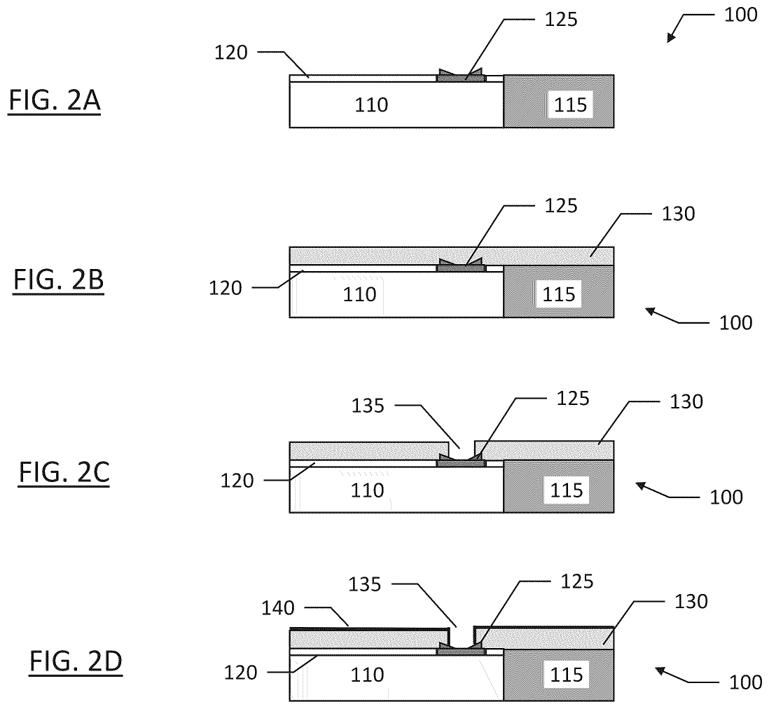

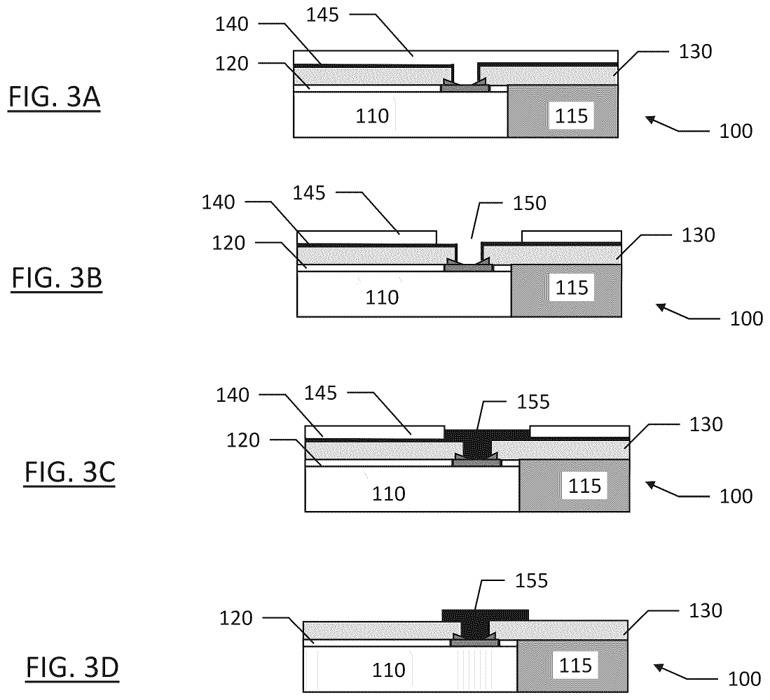

FIGS. 2A through 3D illustrate the process of using multiple redistribution layers to relocate contact pads of wafer-level packaging. As shown in FIG. 2A, a known good die (KGD) of a wafer 110 is shown adjacent to a dry film EMC 115 (Epoxy Molding Compound) of the wafer-level package 100. A contact pad 125 is on top of the wafer 110, and the surface of the wafer is shown coated with a passivation layer 120. In FIG. 2B, the wafer 110 and EMC 115 are laminated with an Ajinomoto Build-up Film (ABF) to form a redistribution layer 130. The redistribution layer 130 is processed as shown in FIG. 2C to expose the contact pad 125. The processing can include drilling, etching, or other known process for exposing the contact pad 125 through the redistribution layer 130. The redistribution layer 130 forms a barrier over the wafer 110 and the EMC 115 save for the exposed contact pads 125. The redistribution layer 130 is coated with an electroless copper seed layer 140 as shown in FIG. 2D. This process prepares the redistribution layer 130 for electroplating to provide the electroplated layer with improved adherence to the surface of the wafer-level package 100.

FIG. 3A illustrates the deposition of a photoresist dry film lamination layer 145. This photoresist layer is a light-sensitive material that can be used to form a patterned coating on a surface. The substrate is coated with the photoresist dry film lamination layer 145 which is processed to expose a portion of the surface beneath. According to an example embodiment, a pattern mask is applied. The patterned mask provides an opaque pattern of the photoresist dry film lamination layer 145 that is to remain in place, while a transparent or translucent portion of the mask allows light to pass through to the photoresist dry film lamination layer 145. The portions of the layer exposed to light are degraded, such that after removal of the mask, a developer can be used to dissolve the portions of the photoresist dry film lamination layer 145 that were exposed to light. According to another embodiment, a mask may be omitted in favor of laser direct imaging which can guide a laser to shine on only portions of the photoresist dry film lamination layer that are to be exposed to light. This process can be more efficient and is at least as effective as the process employing a mask. FIG. 3B illustrates the remaining pattern of the photoresist dry film lamination layer 145 and void 150 where the layer was dissolved and washed away. Copper plating is performed and a copper trace 155 is deposited in the void 150 as shown in FIG. 3C.

FIG. 3D illustrates the copper trace 155 remaining after the photoresist dry film lamination layer 145 is stripped and the copper seed layer 140 is etched to expose the ABF film redistribution layer 130. As shown, this process can provide some degree of relocation of the contact pad 125 based on vertical and lateral transitions of the copper trace 155. The degree of vertical movement is based on a thickness of the redistribution layer 130. The degree of lateral movement of the trace is limited based on a pattern on a surface of the redistribution layer 130. As many wafer-level packages include a plurality of contact pads and therefore associated copper traces. Further, as wafer-level packaging size is critical, and the sizes are shifting to smaller and smaller packages, the amount of lateral movement on any given redistribution layer is limited. Thus, multiple redistribution layers are employed to relocate a contact for the contact pad to any significant degree.

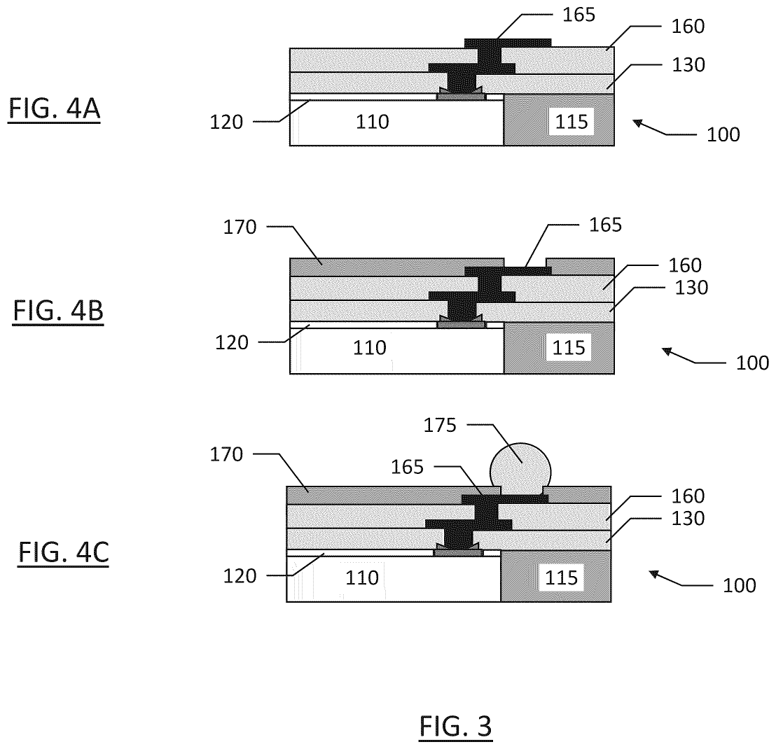

FIG. 4A illustrates an example embodiment with the first redistribution layer 130 and a second redistribution layer 160, where the second redistribution layer is formed using the processes described in FIGS. 2B through 3D. The process of forming redistribution layers and associated copper traces can continue as necessary to move a location for a solder ball used for a contact pad. As additional redistribution layers are added, a build-up of material leads to a substantial increase in thickness of the wafer-level package. This thickness can be undesirable in embodiments where overall package size is important, such as in mobile devices and other electronic devices that benefit from small form factors.

FIG. 4B illustrates the process that follows the final redistribution layer, where a solder mask layer 170 is applied to a surface of the second redistribution layer 160. The solder mask layer 170 covers the surface of the wafer-level package except for the areas that are to receive solder balls. In the illustrated embodiment of FIG. 4B, solder pad 165 remains exposed, such that solder ball 175 can be deposited on the solder pad 165 as illustrated in FIG. 4C.

The redistribution layers described above can introduce failure modes for a wafer-level package. For example, each redistribution layer adds the possibility of delamination between the redistribution layer and the underlying substrate. As more redistribution layers are added, this possibility increases accordingly. Further, each redistribution layer adds a sequence of manufacturing operations as described above with respect to FIGS. 2A through 3D. The added manufacturing operations introduces complexity to the manufacturing process and reduces efficiency. Each additional redistribution layer consumes manufacturing time and resources that reduces throughput. Demand for wafer-level packages is ever-increasing as technology advances and semiconductor chips are in high-demand. Thus, wafer-level package manufacturing efficiency is important. Further, each redistribution layer adds thickness to the wafer-level package, which can lead to an undesirable overall thickness of the wafer-level package, particularly in devices where packaging space is at a premium.

Embodiments described herein improve upon existing technology by offering a method, apparatus, and system for relocating contacts for a contact pad using fewer manufacturing operations and fewer redistribution. Further, embodiments can be of a thinner overall thickness while increasing manufacturing efficiency and reducing the opportunity for defects. Embodiments described herein employ a multi-axis laser drill to drill through a redistribution layer at a non-vertical angle, providing relocation of a contact for a contact pad in a horizontal direction without necessitating multiple redistribution layers. Further, embodiments can reduce the number of manufacturing operations and increase overall efficiency.

The aforementioned prior art process of relocating I/O contacts through multiple redistribution layers is cumbersome and inefficient. Embodiments provided herein capitalize on advances in laser drilling technology to reduce the number of operations required to relocate I/O contacts from an IC to a wafer-level package.

Rather than using multiple layers of ABF for redistribution, embodiments employ a single layer of ABF and use a 6-axis laser drill to drill through the layer at an angle to relocate the I/O contact from the IC to a different position atop the single layer of ABF. The process is illustrated and described below.

Using the process described and illustrated below, contact relocation can be performed with substantially fewer operations in a process that is highly efficient and effective. The 6-axis laser drill can drill a 25 micron hole down to an IC contact pad at an angle of 18-degrees from horizontal. These current limitations may be improved upon with advancing laser drill technology having smaller hole diameters and shallower angles of incidence. The angle can vary with the multi-axis laser drill, where the angle relative to a horizontal plane corresponding to a surface of the wafer can be generally between 10-degrees and 80-degrees given advances in laser drill technology. The axis along which the hole is formed is generally neither vertical nor horizontal. A hole can be vertical for a contact that is not moving laterally relative to a contact pad; however, such a hole does not require the multi-axis laser drill described herein.

The amount of lateral movement of a contact of the IC to a contact of the I/O is dependent upon the angle of incidence of the laser drill bore and the thickness of the ABF layer. A thicker ABF layer allows for greater lateral movement of the contact from the original position on the IC. Embodiments of the invention achieve relocation of contact positions with fewer operations and greater flexibility. Further, RDL layers introduce opportunities for failures through delamination between layers, a problem overcome by the methods described herein.

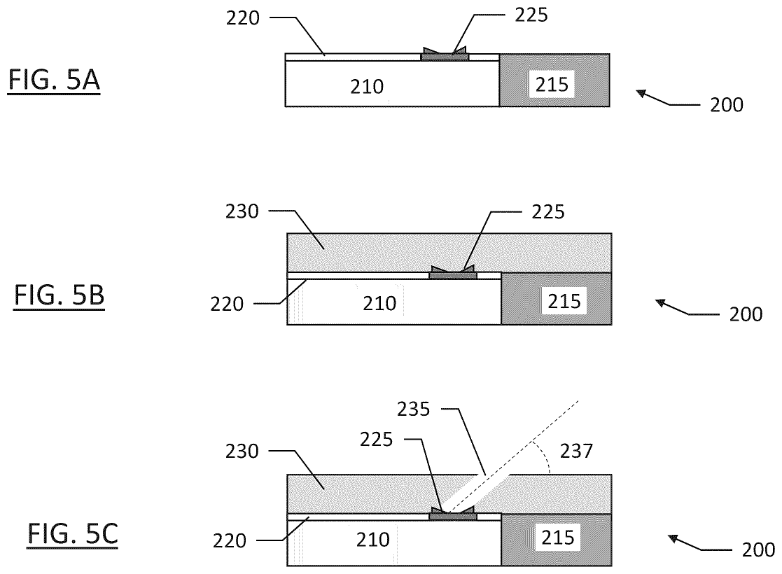

FIG. 5A illustrates a known good die (KGD) of a wafer 210 adjacent to a dry film EMC 215 of the wafer level package 200. A contact pad 225 is on top of the wafer 210, and the surface of the wafer is shown coated with a passivation layer 220. In FIG. 5B, the wafer 210 and EMC 215 are laminated with an Ajinomoto Build-up Film to form a redistribution layer 230. A laser drill is then used to drill through the redistribution layer 230. The laser drill of example embodiments described herein is a multi-axis laser drill, such as a 6-axis laser drill. The laser drill is a multi-axis laser drill to enable drilling through the redistribution layer 230 at an angle that is off-vertical, or not aligned with the vertical axis defined orthogonal to a major surface of the wafer 210.

FIG. 5C illustrates a hole 235 drilled by the multi-axis laser drill through the redistribution layer 230. The hole 235 is at an angle 237 relative to the horizontal plane along which the wafer extends. This angled hole 235 provides a lateral offset between the contact pad 225 and a contact that will be formed for a solder ball. The hole is as small as around 25 microns in diameter. Once the hole is drilled using the multi-axis laser drill, the contact pad 225 is de-smeared. The de-smearing process provides a mechanism by which friction-melted resin and drilling debris, such as from the redistribution layer 230, are removed from the hole 235. This can be achieved, for example, using permanganate or plasma treatment. Further, the contact pad 225 can have its surface abraded or roughened by micro roughening to improve adherence and coating adhesion.

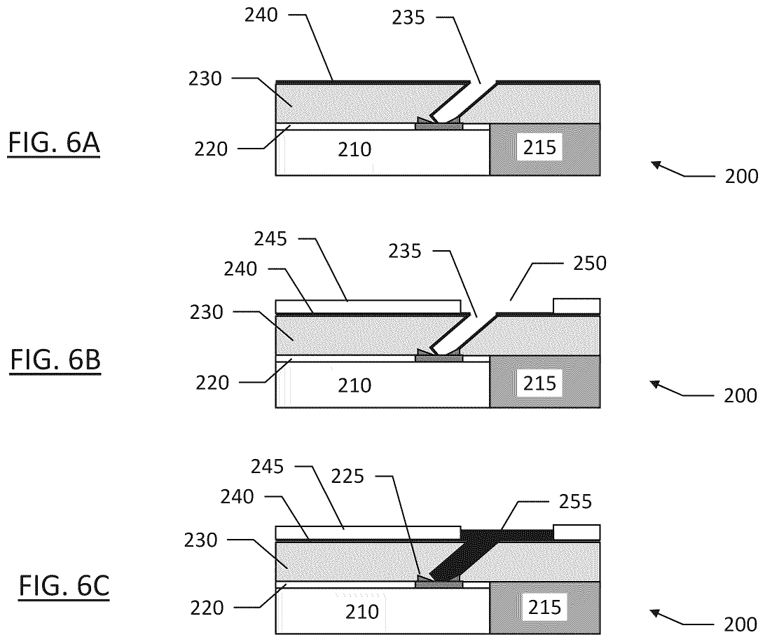

FIG. 6A illustrates an application of a electroless copper seed layer 240. This seed layer covers the redistribution layer 230 and the inside of the hole 235 down to the contact pad 225. A photoresist dry film lamination layer 245 is applied as shown in FIG. 6B. While a photo mask can be employed to cure only a portion of the photoresist dry film lamination layer 245, a laser direct imaging process may optionally be used to cure portions of the photoresist dry film lamination layer 245, while uncured portions may be dissolved or washed away to leave void 250 as shown in FIG. 6B. The void 250 can then be filled with copper using a copper plating operation shown in FIG. 6C, where the copper trace 255 has filled the void 250 and formed contact with the contact pad 225.

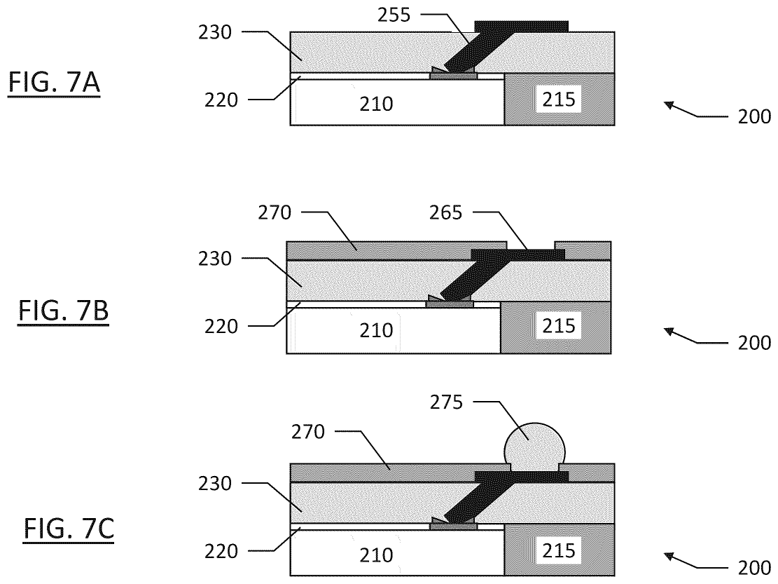

FIG. 7A illustrates the copper trace 255 remaining after the photoresist dry film lamination layer 245 is stripped and the copper seed layer 240 etched to expose the ABF film redistribution layer 230. As shown, this process can provide some degree of relocation of the contact pad 225 based on angled path of the copper trace 255. The degree of vertical movement is based on a thickness of the redistribution layer 230. The degree of lateral movement of the trace is based on an angle 237 at which the multi-axis laser drill forms the hole depicted in FIG. 5C and a thickness of the redistribution layer.

FIG. 7B illustrates the process that follows the formation of copper trace 255, where a solder mask layer 270 is applied to a surface of the redistribution layer 230. The solder mask layer 270 covers the surface of the wafer-level package except for the areas that are to receive solder balls. In the illustrated embodiment of FIG. 7B, solder pad 265 remains exposed, such that solder ball 275 can be deposited on the solder pad 265 as illustrated in FIG. 7C.

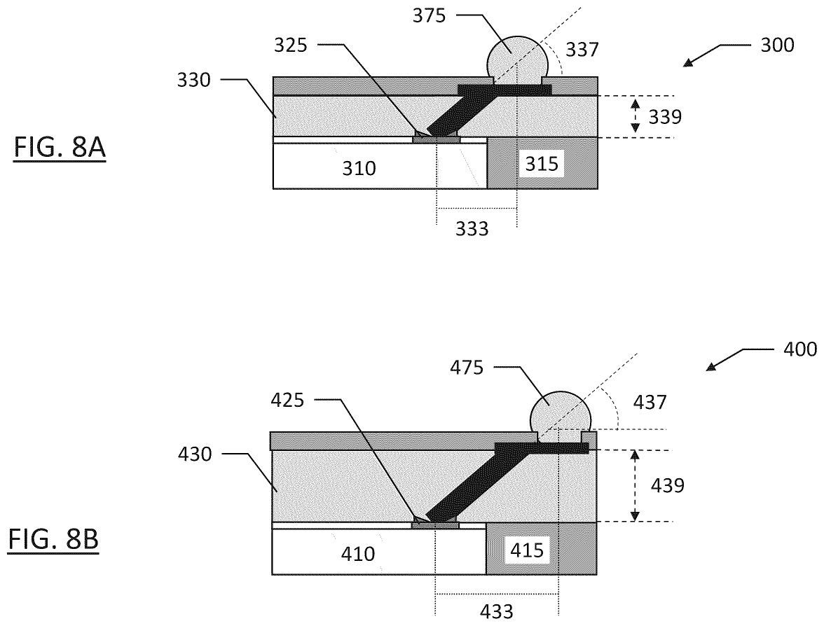

As noted above, the degree of possible lateral movement of the location of the contact pad 225 and the solder ball 275 is based on the angle at which the multi-axis drill forms the hole and the thickness of the redistribution layer. FIGS. 8A and 8B illustrate the effect redistribution layer thickness has on the ability to laterally move a solder ball connection. In FIG. 8A, the wafer 310 and EMC 315 are shown, with the redistribution layer 330 having a thickness 339. The solder ball 375 is positioned a distance 333 from the original contact pad 325 location. FIG. 8B illustrates the wafer 410 and EMC 415 with a redistribution layer 430 having a thickness 439. The angle 437 is equal to the angle 337. However, as thickness 439 of the redistribution layer 430 is substantially larger than thickness 339 of redistribution layer 330, the degree of lateral movement for the wafer-level package 400 is greater at distance 433 than the degree of lateral movement for the wafer-level package 300 at distance 333.

According to embodiments described herein, a relatively thicker redistribution layer can provide greater flexibility in relocation of contact pads. Using a multi-axis laser drill allows the angle of drilling to be controlled precisely, and therefore define a degree of lateral movement from a contact pad based on the angle at which a hole is drilled. Further, this degree of lateral movement can be any direction on the surface plane of the redistribution layer.

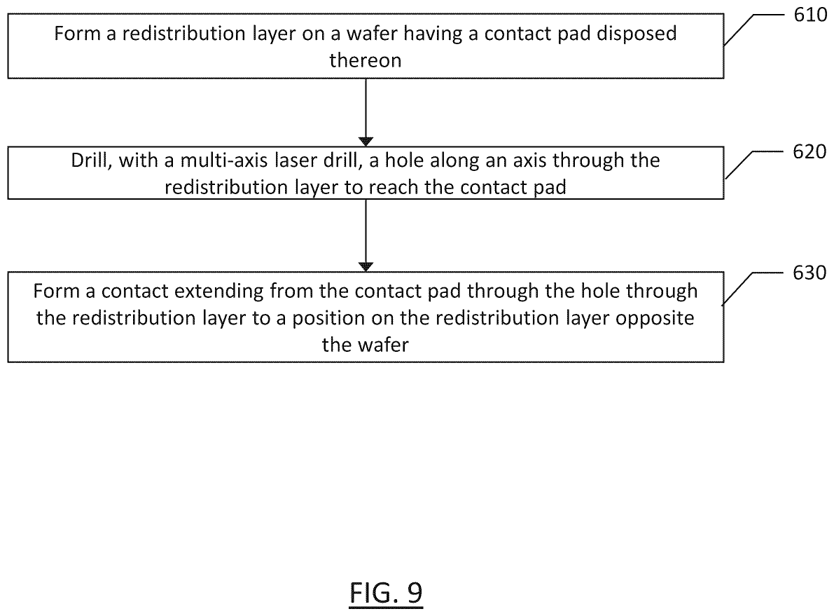

FIG. 9 illustrates an example block diagram of a flowchart of operations for using a multi-axis laser drill to drill off-vertical holes through a redistribution layer in order to relocate I/O contact pads in a wafer-level package in accordance with one or more embodiments of the present disclosure. In various embodiments one or more of the operations may be omitted or repeated. It will also be appreciated that other operations not described herein may also occur. According to the illustrated embodiment, a redistribution layer is formed on a wafer having a contact pad disposed thereon at 610. The wafer defines a plane along a major horizontal surface on which the contact pad is disposed. At 620, a hole is drilled with a multi-axis laser drill along an axis through the redistribution layer to reach the contact pad. The axis of the hole through the redistribution layer is at an angle relative to the plane that is neither parallel nor orthogonal. A contact is formed at 630 extending from the contact pad through the hole through the redistribution layer to a position on the redistribution layer opposite the wafer.

Operations and/or functions of the present disclosure have been described herein, such as in flowcharts or figures associated with flowcharts. While operations and/or functions are illustrated in a particular order, this should not be understood as requiring that such operations and/or functions be performed in the particular order shown or in sequential order, or that all illustrated operations be performed, to achieve desirable results. In certain circumstances, operations and/or functions in alternative ordering may be advantageous. In some cases, the actions recited in the claims may be performed in a different order and still achieve desirable results. Thus, while particular embodiments of the subject matter have been described, other embodiments are within the scope of the following claims.

While this specification contains many specific embodiments and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

While this detailed description has set forth some embodiments of the present invention, the appended claims cover other embodiments of the present invention which differ from the described embodiments according to various modifications and improvements.

Within the appended claims, unless the specific term “means for” or “step for” is used within a given claim, it is not intended that the claim be interpreted under 35 U.S.C. § 112, paragraph 6.

1. A method of manufacturing a wafer-level package comprising:
forming a redistribution layer on a wafer having a contact pad disposed thereon, wherein the wafer defines a plane along a major horizontal surface on which the contact pad is disposed;
drilling, with a multi-axis laser drill, a hole along an axis through the redistribution layer to reach the contact pad, wherein the axis of the hole through the redistribution layer is at an angle relative to the plane that is neither parallel nor orthogonal; and
forming a contact extending from the contact pad, through the hole through the redistribution layer, to a position on the redistribution layer opposite the wafer.

2. The method of claim 1, wherein the axis of the hole through the redistribution layer is at an angle relative to the plane that is between 10 degrees and 80 degrees.

3. The method of claim 1, further comprising:
forming a seed layer after drilling; and
applying a photoresist dry film lamination layer over the seed layer, wherein the contact extending from the contact pad is formed where the photoresist dry film lamination layer was not cured.

4. The method of claim 1, further comprising:
applying a solder mask over the redistribution layer; and
attaching a solder ball at the contact that is in electrical communication with the contact pad.

5. The method of claim 1, wherein the redistribution layer comprises an Ajinomoto Build-up Film.

6. The method of claim 1, wherein the contact pad is a contact pad of an input/output (I/O) portion of a semiconductor chip.

7. The method of claim 1, further comprising:
determining the angle relative to the plane for the hole through the redistribution layer based on a thickness of the redistribution layer and a required position of the contact relative to the contact pad.

8. The method of claim 1, wherein the hole is around 25 microns in diameter.

9. The method of claim 1, wherein the contact pad is a first contact pad, the hole is a first hole, the axis is a first axis, the contact is a first contact, and the angle is a first angle, the method further comprising:
drilling, with the multi-axis laser drill, a second hole along a second axis through the redistribution layer to reach a second contact pad of the wafer, wherein the second axis of the second hole through the redistribution layer is at a second angle relative to the plane that is different from the first angle; and
forming a second contact extending from the second contact pad, through the hole through the redistribution layer, to a position on the redistribution layer opposite the wafer.

10. The method of claim 1, wherein drilling a hole along the axis through the redistribution layer to reach the contact pad further comprises:
removing one or more of friction-melted resin or drilling debris from the hole after drilling.

11. The method of claim 10, wherein removing one or more of friction-melted resin or drilling debris from the hole after drilling comprises treating the hole using at least one of permanganate or plasma treatment.

12. A wafer-level package comprising:
a silicon wafer, wherein the silicon wafer defines a plane along a major horizontal surface;
a contact pad on the major horizontal surface of the silicon wafer;
a redistribution layer on the silicon wafer;
a hole through the redistribution layer, wherein the hole defines an axis along which the hole extends, where the axis is at an angle relative to the plane of between about 10 degrees and 80 degrees; and
a contact extending from the contact pad, through the hole through the redistribution layer, to a position on the redistribution layer opposite the silicon wafer.

13. The wafer-level package of claim 12, wherein the hole through the redistribution layer is formed using a multi-axis laser drill.

14. The wafer-level package of claim 12, further comprising:
a solder mask over the redistribution layer; and
a solder ball on the contact that is in electrical communication with the contact pad.

15. The wafer-level package of claim 12, wherein the redistribution layer comprises an Ajinomoto Build-up Film.

16. The wafer-level package of claim 12, wherein the contact pad is a contact pad of an input/output (I/O) portion of a semiconductor chip.

17. The wafer-level package of claim 12, wherein the hole is around 25 microns in diameter.

18. A system for producing a wafer-level package comprising:
a wafer having contact pads and a redistribution layer covering a major surface of the wafer and the contact pads; and
a multi-axis laser drill, wherein the multi-axis laser drill is configured to drill holes at various different angles relative to a plane defined by the major surface of the wafer through the redistribution layer to reach at least one of the contact pads.

19. The system of claim 18, wherein the multi-axis laser drill is configured to drill holes at between about 10 degrees and about 80 degrees from the plane defined through the wafer.

20. The system of claim 18, wherein the multi-axis laser drill is configured to drill holes though the redistribution layer of at least 25 microns in diameter.
